(19) United States
(12) Patent Application Publication
(10) Pub. No.: US 2021/0060924 A1
(43) Pub. Date: Mar. 4, 2021

(54) LOW ENERGY E-BEAM CONTACT PRINTING LITHOGRAPHY

(71) Applicant: Takao Utsumi, Tokyo (JP)

(72) Inventor: Takao Utsumi, Tokyo (JP)

(21) Appl. No.: 16/558,657

(22) Filed: Sep. 3, 2019

(51) Int. Cl. B41C 1/10; H01L 23/544; G03F 7/00

(52) U.S. Cl. CPC B41C 1/1058; B41C 1/1041; G03F 7/0002; H01L 23/544

(57) ABSTRACT

An approach is provided for transferring one or more device patterns of a template mask wafer onto a device pattern wafer. The approach includes positioning a template mask wafer on a device pattern wafer. The template mask wafer may include a membrane formed in a substrate layer, a first layer on a first back surface of the substrate layer, one or more mask alignment marks and one or more template device patterns in the membrane, and a second layer on a second back surface of the first layer. The device pattern wafer may include a semiconductor wafer, a third layer on a semiconductor wafer, one or more alignment marks in the third layer, and a fourth layer on the third layer. The approach includes aligning the one or more mask alignment marks with the one or more alignment marks. The approach includes transferring one or more template device patterns onto the device pattern wafer.

### BACKGROUND

The disclosure herein relates generally to semiconductor lithography, and more particularly, to low energy electron-beam (e-beam) contact printing lithography.

Conventional e-beam projection lithography, such as low energy e-beam projection lithography (LEEPL), may use stencil masks that have holes to form a device pattern during an exposure process. Typically, a number of complementary stencil masks may be required to write more complex patterns, such as donut-shaped patterns. For instance, if only one mask were used to write donut-shaped patterns, the mask would not be able to include the circular center of the donut-shaped pattern, as the circular center of the donut-shaped pattern would not be supported by the main portion of the mask. However, using more than one mask may increase the time to form device patterns in a semiconductor wafer, and exposing the layers multiple times may reduce the throughput of the system on various layers. Additionally, another process is required to align the extra masks, thereby increasing the complexity of forming the semiconductor. In conventional e-beam lithography, a large gap, e.g., about 10 micrometers to about 40 micrometers, is typically formed between the resist layer and the mask layer. During the e-beam projection process, the electron optics, such as space charge and lens aberration, of the LEEPL system create a beam blur within the large gap, thereby deteriorating the resolution of the LEEPL system. Moreover, in conventional e-beam lithography, the resist layer and the mask layer are floating in a vacuum during the writing process. Consequently, heat conduction may only occur through a peripheral portion of the mask layer. That is, if the power of the e-beam increases, the LEEPL system may not be able to maintain a low temperature rise and thus a low thermal distortion. As the temperature rise and thermal distortion of the mask layer limit the e-beam current, the throughput of the conventional LEEPL system may be limited.

### SUMMARY

The summary of the disclosure is given to aid understanding of semiconductor structures, processes, and methods of low energy e-beam contact printing lithography (LEECOPL), and not with an intent to limit the disclosure. The disclosure is directed to a person of ordinary skill in the art. It should be understood that various aspects and features of the disclosure may advantageously be used separately in some instances, or in combination with other aspects and features of the disclosure in other instances.

Accordingly, variations and modifications may be made to semiconductor structures, processes, and methods of LEECOPL to achieve different effects. It is to be understood that both the foregoing general description and the following detailed description are exemplary and explanatory only and are not restrictive of the broad inventive concepts upon which the embodiments disclosed herein are based.

In one or more cases, the disclosed technology relates to a method of forming a template mask wafer. In one or more cases, the method includes forming a membrane in a substrate layer. In one or more cases, the method includes forming a first layer on a first back surface of the substrate layer, in which the first layer is semitransparent. In one or more cases, the method includes forming a second layer on a second back surface of the first layer, in which the second layer formed from a material having a low coefficient of friction. In one or more cases, the method includes writing one or more mask alignment marks and one or more template device patterns in the membrane, thereby forming the template mask wafer.

In one or more cases, the disclosed technology relates to a method of transferring one or more device patterns of a template mask wafer onto a device pattern wafer. In one or more cases, the method includes positioning the template mask wafer on the device pattern wafer. In one or more cases, the template mask wafer includes a membrane formed in a substrate layer, a first layer disposed on a first back surface of the substrate layer, one or more mask alignment marks and one or more template device patterns in the membrane, and a second layer disposed on a second back surface of the first layer. In one or more cases, the device pattern wafer comprising a semiconductor wafer, a third layer on a semiconductor wafer, one or more alignment marks in the third layer, and a fourth layer on the third layer. In one or more cases, the method includes aligning the one or more mask alignment marks of the template mask wafer with the one or more alignment marks of the device pattern wafer. In one or more cases, the method includes transferring the one or more template device patterns onto the device pattern wafer. In one or more cases, the first layer is semitransparent, and the second layer has a low coefficient of friction.

The foregoing and other objects, features and advantages of the disclosure will be apparent from the following descriptions of the embodiments and as illustrated in the accompanying drawings.

### BRIEF DESCRIPTION OF THE DRAWINGS

The following drawings are illustrative of particular embodiments of the disclosure and therefore do not limit the scope of the disclosure. The drawings are not to scale and are intended for use in conjunction with the explanations in the following detailed description. It may be noted that a numbered element is numbered according to the figure in which the element is introduced, and is typically referred to by that number throughout succeeding figures.

The various aspects, features and embodiments of low energy e-beam contact printing lithography (LEECOPL) will be better understood when read in conjunction with the figures provided. Embodiments are provided in the figures for the purpose of illustrating aspects, features, and/or various embodiments of LEECOPL, but the claims should not be limited to the precise arrangement, structures, features, aspects, assemblies, systems, embodiments, or devices shown. The arrangements, structures, subassemblies, features, aspects, methods, processes, embodiments, and devices shown may be used singularly or in combination with other arrangements, structures, assemblies, subassemblies, systems, features, aspects, embodiments, methods and devices.

FIG. 1 illustrates a side view of a membrane formed in a substrate layer.

FIG. 2 is a cross-sectional view illustrating one or more layers formed on the substrate layer.

FIG. 3A is a cross-sectional view illustrating a template mask formed in the substrate layer.

FIG. 3B is an enlarged view of the template mask formed in the substrate layer of FIG. 3A.

FIG. 3C is a top view of one or more mask alignment marks formed in the substrate layer of FIG. 3A.

FIG. 4 is a cross-sectional view illustrating the mask alignment marks of the template mask being aligned with alignment marks of a semiconductor wafer, and writing template device patterns to the semiconductor wafer via contact printing.

FIG. 5A illustrates an example of E-optics and beam blur for a LEEPL system.

FIG. 5B illustrates a graphical representation of a beam blur profile for the LEEPL system of FIG. 5A.

FIG. 5C illustrates an example of E-optics and beam blur for a LEECOPL system.

FIG. 5D illustrates a graphical representation of a beam blur profile for the LEECOPL system of FIG. 5C.

FIG. 5E is an enlarged view of an example E-optics path and beam blur for the LEECOPL system of FIG. 5C.

FIG. 5F is an enlarged view of an example E-optics path and beam blur for the LEECOPL system of FIG. 5D.

FIG. 6 is a simulation illustrating a primary electron's forward-scattering profile.

FIG. 7 illustrates a temperature rise causing thermal distortion of a mask wafer and the device pattern wafer.

### DETAILED DESCRIPTION

The following discussion omits or only briefly describes conventional features of semiconductor lithography, which are apparent to those skilled in the art. It is noted that various embodiments are described in detail with reference to the drawings, in which like reference numerals represent like parts and assemblies throughout the several views. Reference to various embodiments does not limit the scope of the claims attached hereto. Additionally, any examples set forth in this specification are intended to be non-limiting and merely set forth some of the many possible embodiments for the appended claims. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc. It must also be noted that, as used in the specification and the appended claims, the singular forms “a,” “an” and “the” include plural referents unless otherwise specified, and that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element such as a layer, region, or substrate is referred to as being “on”, “over”, “beneath”, “below”, or “under” another element, it may be present on or below the other element or intervening elements may also be present. In contrast, when an element is referred to as being “directly on”, “directly over”, “directly beneath”, “directly below”, or “directly contacting” another element, there may be no intervening elements present. Furthermore, the terminology used herein is for the purpose of describing particular embodiments only and is not intended to be limiting of the embodiments.

In the interest of not obscuring the presentation of embodiments in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments described herein.

Embodiments of the disclosure relate generally to semiconductor lithography, and more particularly, to low energy e-beam contact printing lithography (LEECOPL). Embodiments of LEECOPL are described further below with reference to the Figures.

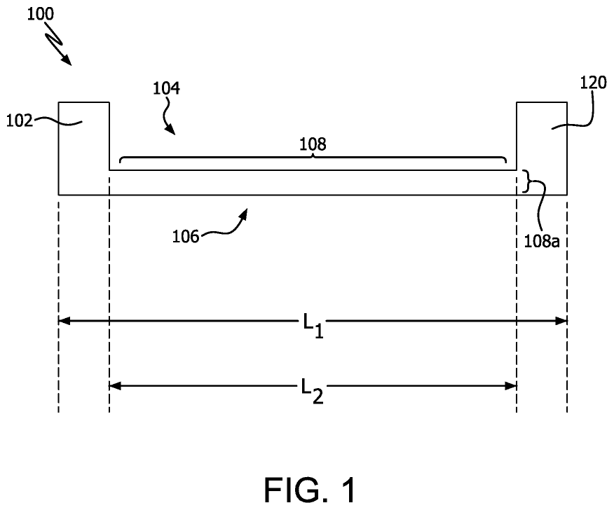

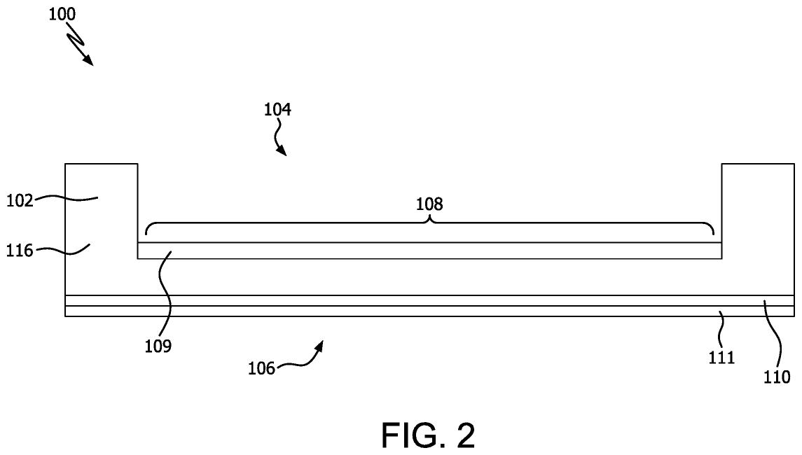

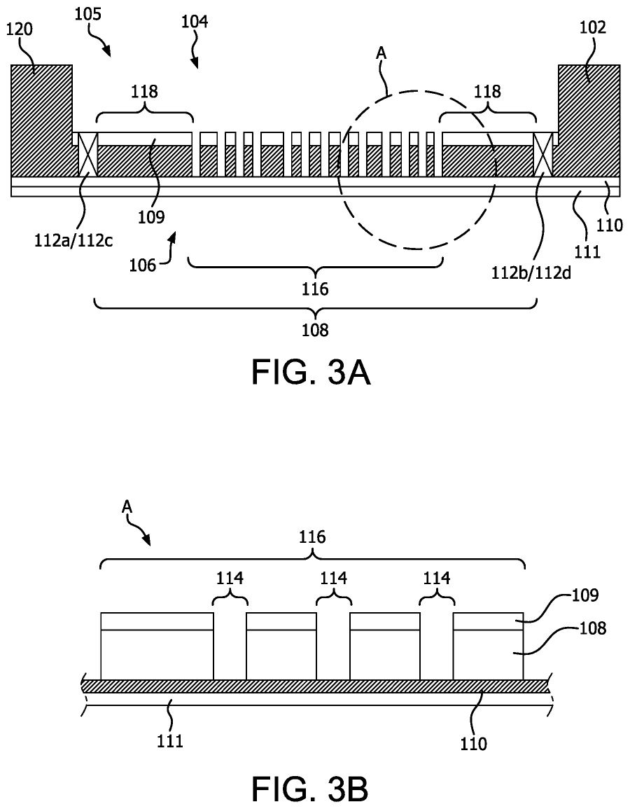

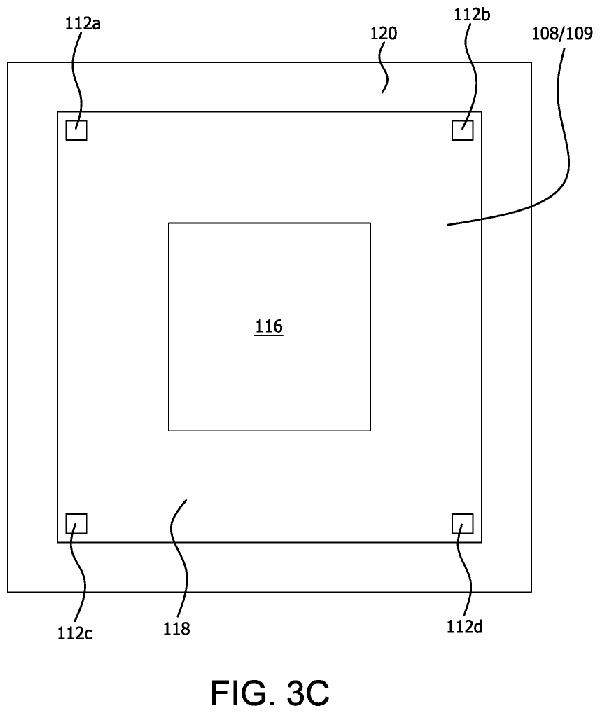

FIGS. 1-3C illustrate a process 100 of forming a mask wafer 105 that includes a template mask 116 having a template device pattern 114. FIG. 1 illustrates a side view of a membrane 108 formed in a substrate layer 102. FIG. 2 is a cross-sectional view illustrating one or more layers formed on the substrate layer 102. FIG. 3A is a cross-sectional view illustrating the template mask 116 formed in the substrate layer 102. FIG. 3B is an enlarged view A of the template mask 116 formed in the substrate layer 102. FIG. 3C is a top view of one or more mask alignment marks formed in the substrate layer 102.

The substrate layer 102 is a semiconductor wafer composed of material, such as, silicon (Si), undoped Si, n-doped Si, p-doped Si, single crystal Si, polycrystalline Si, amorphous Si, or the like. In one or more cases, the substrate layer 102 is preferably composed of Si. Non-limiting examples of compound semiconductor materials include gallium arsenide, indium arsenide, and indium phosphide. The substrate layer 102 may have a length L₁ of 3 centimeters (cm) to 4 cm or about 3 cm to about 4 cm by a width of 3 cm to 4 cm or about 3 cm to about 4 cm. It is noted that the size of the substrate layer 102 may vary depending on the requirements for the template device pattern 114 of the mask wafer 105.

In one or more cases, the membrane 108 may be formed in the substrate layer 102 using an etching technique, such as, for example, dry etching, reactive ion etching (RIE), wet etching, or isotropic wet etching. The membrane 108 may be a part of and formed of the same material as the substrate layer 102. One or more template device patterns 114 may be formed in the membrane 108. The membrane 108 may be etched into a top 104 of the substrate layer 102. In some scenarios the membrane 108 may have a length L₂ of 1 cm to 3 cm or about 1 cm to about 3 cm by a width of 1 cm to 3 cm or about 1 cm to about 3 cm. In some scenarios, the thickness 108a of the membrane 108 may have a thickness that ranges from at or about 30 nanometers (nm) to 200 nm thick, and preferably be at or about 100 nm thick for a critical dimension (CD) of 10 nm and below. The CD may be the minimum line width in which a machine can write template device patterns 114 in the membrane 108. It should be noted that the thickness 108a of the membrane 108 may vary depending on structural stability requirements of the template mask 116.

In one or more cases, a first layer 110 is formed on the substrate layer 102. The first layer 110 may be formed on the back surface 106 of the substrate layer 102 using a deposition technique, such as, for example, chemical vapor deposition (CVD), plasma enhanced CVD (PECVD), thermal CVD (THCVD), sputtering, or spin-on deposition. In one or more cases, the first layer 110 may be formed on the entirety of the back surface 106, i.e., a major back surface, of the substrate layer 102. In one or more other cases, the first layer 110 may be formed on a portion of the back surface 106, a minor back surface, of the substrate layer 102 that covers the membrane 108. In one or more cases, the first layer 110 may be formed as a smooth continuous layer on the back of the membrane 108.

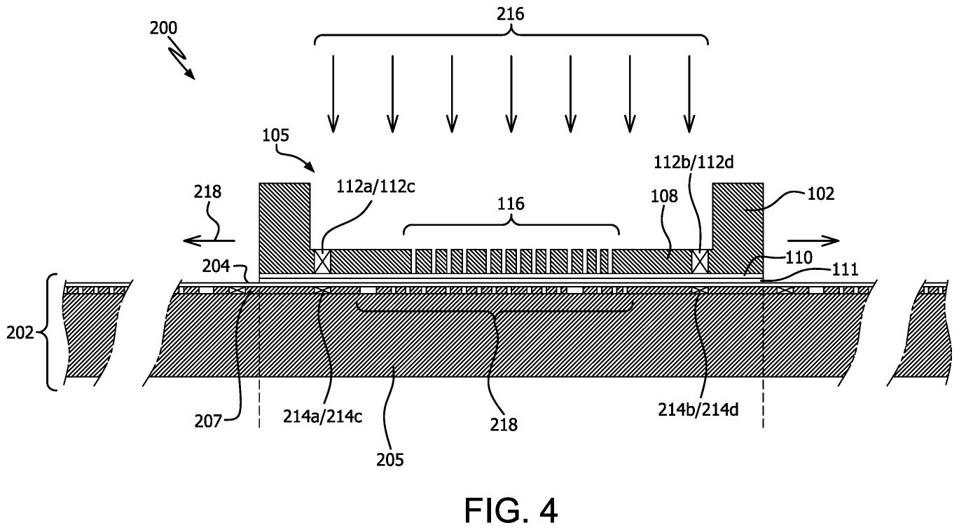

In one or more cases, the first layer 110 is composed of a material having strong anti-frictional wear characteristics. For example, the first layer 110 may be composed of amorphous carbon, a diamond film, or a doped Si material, such as n-doped Si or p-doped Si. The first layer 110 may act as an etching-stop when writing template device patterns 114 into the membrane 108. By forming the first layer 110, which acts as an etching-stop, on the back surface 106 of the substrate layer 102, a variety of complex template device patterns 114 may be written into the membrane 108 by an e-beam writer. For example, instead of using a number of complementary stencil masks as used in conventional e-beam lithography, to write a donut-shaped pattern, the first layer 110 may be used to support the circular center of the donut-shaped pattern. That is, only one mask, such as the mask wafer 105, is needed to write complex template device patterns 114 into a device pattern wafer 202, as shown in FIG. 4. Moreover, the time to write the complex template device patterns 114 into the device pattern wafer 204 is reduced compared to that of a conventional e-beam lithography system, as only one mask is needed.

The thickness of the first layer 110 may be at or about 2 nm to 10 nm thick, and preferably at or about 3 nm thick. The first layer 110 is semitransparent or near transparent for the cases in which the energy range of the e-beam of the LEECOPL is 2 kilovolts (kV), about 2 kV to 8 kV or 8 kV, or more preferably 3 kV. That is, the first layer 110 in the LEECOPL may serve the same function as a quartz plate for optical lithography systems. For example, the first layer 110 allows the LEECOPL system to write various device patterns, including donut-shaped patterns, using a single template mask. In one or more cases, the first layer 110 is semitransparent or near transparent to the e-beam passing through the mask wafer 105. For example, the semitransparent first layer 110 may allow 99% or about 99% of the e-beam to pass through the semitransparent first layer 110, and may cause 1% or about 1% of the e-beam to scatter inside the semitransparent first layer 110 and exit the semitransparent first layer 110 at an angle divergent from the angle in which the e-beam entered the semitransparent first layer 110.

In one or more cases, a second layer 111 is formed on of the first layer 110. The second layer 111 may be formed on the back surface 106 of the substrate layer 102. In one or more cases, the second layer 111 may be formed on a portion of the back surface 106, a minor back surface, of the first layer 110 that covers the membrane 108. In one or more other cases, the second layer 111 may be formed on the entirety of the back surface 106, i.e., a major back surface, of the first layer 110. The second layer 111 may be formed on the back surface 106 of the first layer 110 using a deposition technique, such as, for example, CVD, PECVD, THCVD, sputtering, or spin-on deposition. The second layer 111 may include Polytetrafluoroethylene, Silicon, or other like materials that have a low coefficient of friction. For example, the coefficient of friction for polytetrafluoroethylene may be 0.05 to 0.10. The second layer 111 may protect the membrane 108 from contact friction. In one or more cases, the contact friction may be generated when positioning the mask wafer 105 on a device pattern wafer, such as the device pattern wafer 202. In one or more cases, the thickness of the second layer 111 may be at or about 3 nm.

In one or more cases, a resist layer 109 is formed on the membrane 108. The resist layer 109 may be formed on the top 104 of the membrane 108 using a deposition technique, such as, for example, CVD, PECVD, THCVD, sputtering, or, more preferably, spin-on deposition. In one or more cases, the first layer 110 and the second layer 111 are formed on the substrate layer 102 before forming the resist layer 109 on the substrate layer 102. In one or more other cases, the resist layer 109 is formed on the substrate layer 102 before forming the first layer 110 and the second layer 111 on the substrate layer 102.

In one or more cases, one or more mask alignment marks, such as mask alignment marks 112a, 112b, 112c, and 112d, are formed in the resist layer 109 and the membrane 108. The mask alignment marks 112a, 112b, 112c, and 112d may be written into the resist layer 109 and the membrane 108 using Nanoimprint Lithography (NIL) or by an e-beam writer. For the cases in which the e-beam writer is used, the top 104 of the resist layer 109 and the membrane 108 are exposed to an e-beam. The e-beam is directed towards the top 104 of the resist layer 109 and the membrane 108, and passes through the resist layer 109 and the membrane 108. The resist layer 109 and the membrane 108 may be etched to create the mask alignment marks 112a, 112b, 112c, and 112d in the membrane 108.

The mask alignment marks 112a, 112b, 112c, and 112d may be arranged around the outer portions 118 of the membrane 108 in a variety of shapes. For example, for the cases in which four mask alignment marks are used, the four mask alignment marks may be arranged in a square shape around the outer portions 118 of the membrane 108, as shown in the top view of FIG. 3C. In the square shape configuration, a mask alignment mark may be arranged orthogonal to the adjacent mask alignment marks. For instance, the mask alignment mark 112a may be arranged orthogonal to mask alignment marks 112b and 112c. In another example, three mask alignment marks may be arranged in a triangular shape around the outer portions 118 of the membrane 108. In yet another example, two mask alignment marks may be arrange linearly from one another, in which each mask alignment mark is positioned on the outer portion 118 of the membrane 108.

In one or more cases, the template device patterns 114 are written into the resist layer 109 and the membrane 108, thereby forming a template mask 116. The template device patterns 114 may be written into the resist layer 109 and the membrane 108 using NIL or by the e-beam writer. For the cases in which the e-beam writer is used, the top 104 of the resist layer 109 and the membrane 108 are exposed to an e-beam. The e-beam is directed towards the top 104 of the resist layer 109 and the membrane 108, and passes through the resist layer 109 and the membrane 108. The resist layer 109 and the membrane 108 may be etched to create the template device patterns 114 in the membrane 108. In one or more cases, the template device patterns 114 are written at the same time as the mask alignment marks 112a, 112b, 112c, and 112d. In one or more other cases, the template device patterns 114 are written before or after the mask alignment marks 112a, 112b, 112c, and 112d are written. The mask wafer 105 may include the mask alignment marks 112a, 112b, 112c, and 112d and the template mask 116 formed in the substrate layer 102. The template mask 116 may also be referred to as a parent mask. In one or more cases, the resist layer 109 may be removed after the template device patterns 116 and the mask alignment marks 112a, 112b, 112c, and 112d are formed in the mask wafer 105.

In one or more cases, a grid 120 surrounds the membrane 108 and the mask alignment marks 112a, 112b, 112c, and 112d. The height of the grid 120 may be greater than the height of the membrane 108 when viewed from the side view of the membrane 108. To position the mask alignment marks 112a, 112b, 112c, and 112d during the pattern writing process, at least a portion of the grid 120 is grabbed to move the mask wafer 105 and to align the mask alignment marks 112a, 112b, 112c, and 112d with corresponding alignment marks, such as alignment marks 214a, 214b, 214c, and 214d, on a device pattern wafer, such as device pattern wafer 202.

FIG. 4 illustrates a process 200 of aligning the mask alignment marks of the template mask 116 to the alignment marks of the device pattern wafer 202, and writing the template device patterns 114 to the device pattern wafer 202 via contact printing. FIG. 4 is a cross-sectional view illustrating the mask alignment marks 112a, 112b, 112c, and 112d of the template mask 116 being aligned with the alignment marks 214a, 214b, 214c, and 214d of the device pattern wafer 202, and the template device patterns 114 of the template mask 116 being written over one or more device patterns 218 of the device pattern wafer 202.

In one or more cases, the device pattern wafer 202 includes a third layer 204 and a fourth layer 207 formed on a semiconductor wafer 205. In one or more cases, the device pattern wafer 202 may have a diameter of 30 cm or about 30 cm. It is noted that the diameter of the device pattern wafer 202 may vary depending on the requirements for the mask pattern.

The semiconductor wafer 205 is composed of a semiconductor material, such as, Si, undoped Si, n-doped Si, p-doped Si, single crystal Si, polycrystalline Si, amorphous Si, Ge, SiGe, SiC, SiGeC, Ga, GaAs, InAs, InP and all other III/V or II/VI compound semiconductors. In one or more cases, the semiconductor wafer 205 is preferably composed of Si. Non-limiting examples of compound semiconductor materials include gallium arsenide, indium arsenide, and indium phosphide.

In one or more cases, the fourth layer 207 is a membrane that includes one or more device patterns 218 and one or more alignment marks, such as alignment marks 214a, 214b, 214c, and 214d. The one or more device patterns 218 and the one or more alignment marks may be formed in a same or similar manner as the template device patterns 114 and the mask alignment marks 112a, 112b, 112c, and 112d being formed in the membrane 108. In one or more cases, the one or more device patterns 218 and the one or more alignment marks may be formed before the template mask 116 is formed in the mask wafer 105. The alignment marks 214a, 214b, 214c, and 214d may be formed in the fourth layer 207 using NIL or by the e-beam writer. The one or more device patterns 218 may be written into the fourth layer 207 using NIL or by the e-beam writer. For the cases in which the alignment marks 214a, 214b, 214c, and 214d and/or the one or more device patterns 218 are written via the e-beam writer, the top of the fourth layer 207 is exposed to an e-beam. In one or more other cases, for example in a first iteration of the lithographic writing process, the fourth layer 207 includes one or more alignment marks, such as alignment marks 214a, 214b, 214c, and 214d, and does not include the one or more device patterns 218. The third layer 204 is a resist layer formed on the fourth layer 207 using a deposition technique, such as, for example, CVD, PECVD, THCVD, sputtering, or spin-on deposition. In one or more cases, the third layer 204 may be formed on the entire top surface of the fourth layer 207. In one or more other cases, the third layer 204 may be formed on a portion of the top surface of the fourth layer 207 that covers the one or more device patterns 218. The third layer 204 may have a thickness of 30 nm or about 30 nm.

To transfer the template device patterns 114 onto the device pattern wafer 202, the mask wafer 105 is positioned on the device pattern wafer 202. In one or more cases, the mask wafer 105 may be positioned on top 104 of the device pattern wafer 202. The mask wafer 105 may be positioned on the device pattern wafer 202 by aligning the mask alignment marks 112a, 112b, 112c, and 112d of the mask wafer 105 with alignment marks, such as alignment marks 214a, 214b, 214c, and 214d, of the device pattern wafer 202. For example, the mask alignment mark 112a is aligned with the alignment mark 214a, the mask alignment mark 112b is aligned with the alignment mark 214b, the mask alignment mark 112c is aligned with the alignment mark 214c, and the mask alignment mark 112d is aligned with the alignment mark 214d. By aligning the mask alignment marks 112a, 112b, 112c, and 112d with alignment marks 214a, 214b, 214c, and 214d of a device pattern wafer 202, the relative position of the template mask 116 against a device pattern 218 on the device pattern wafer 202 is maintained during pattern writing. In one or more cases, mask alignment marks of the mask wafer 105 and the alignment marks of the device pattern wafer 202 may be aligned using a manual process, an automatic alignment process, and/or a vision system alignment process.

Having aligned the one or more mask alignment marks of the mask wafer 105 with the alignment marks of the device pattern wafer 202, the mask wafer 105 and the device pattern wafer 202 are united via a suction force, an electro-static force, or the like to hold the mask wafer 105 and the device pattern wafer 202 together during the e-beam pattern writing process. For the cases in which an electro-static force is used to unite the mask wafer 105 and the device pattern wafer 202, the LEECOPL system is designed to control the contact pressure between the mask wafer 105 and the device pattern wafer 202. For example, the contact pressure used to hold the mask wafer 105 and the device pattern wafer 202 may be set to a minimum amount of pressure capable of maintaining the mask wafer 105 and the device pattern wafer 202 in a contact state. For the cases in which an electro-static force is used to unite the mask wafer 105 and the device pattern wafer 202, the mask wafer 105 and the device pattern wafer 202 are held together via van de Waals forces.

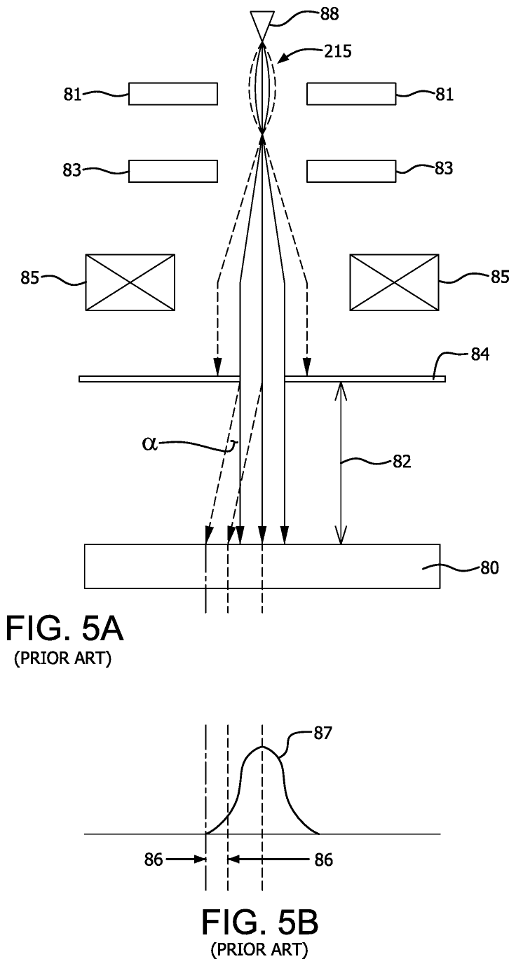

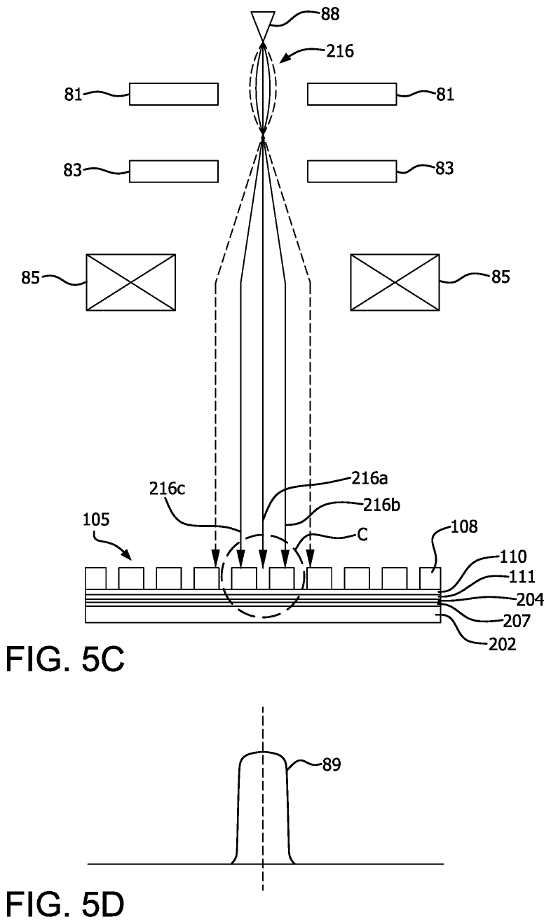

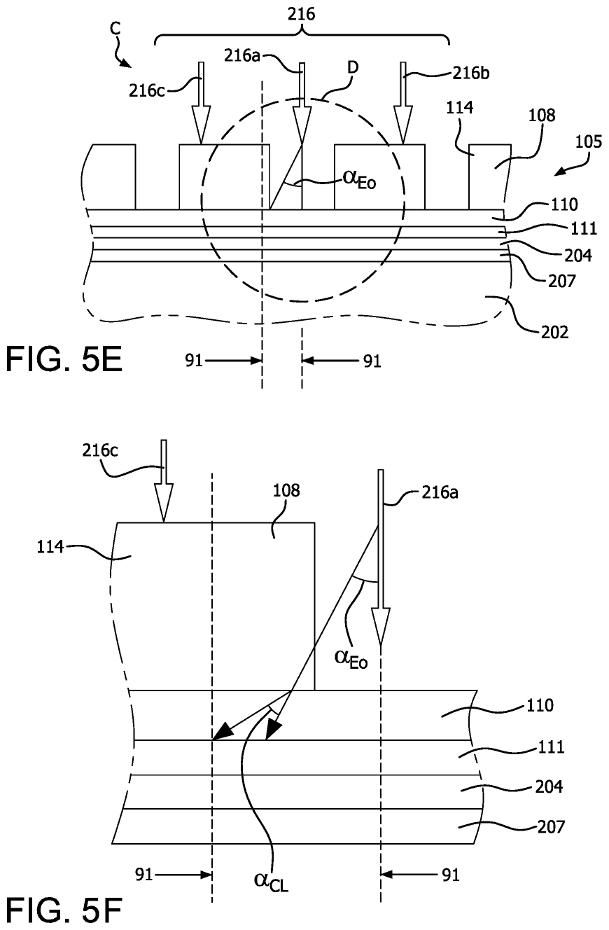

In one or more cases, the device pattern wafer 202 and the mask wafer 105 are united such that there is no gap or substantially no gap between a bottom of the device pattern wafer 202 and a top of the mask wafer 105. For example, the device pattern wafer 202 and the mask wafer 105 are united such that there is no gap or substantially no gap between the top of the third layer 204 and the bottom of the first layer 110 for the cases in which the second layer 111 is not used, or the bottom of the second layer 111 for the cases in which the second layer 111 is used. By having no gap or substantially no gap between the third layer 204 and the first layer 110, the blur of an e-beam 216 passing through the template mask 116 is either negligibly small, as shown in FIG. 5D, or there is no beam-blur due to the electron optics of the LEECOPL system, such as aberrations and/or space charges. Compared to conventional e-beam lithography and, for example, the LEEPL system, by having no gap or substantially no gap between the device pattern wafer 202 and the mask wafer 105 during the e-beam projection process, the resolution of the LEECOPL system is greatly increased. Moreover, as the device pattern wafer 202 and the mask wafer 105 are in direct contact with one another, the heat conduction is more widely distributed throughout the mask wafer 105, allowing the LEECOPL system to maintain a low temperature rise. Therefore, the LEECOPL system may maintain a low distortion, in particular, for systems utilizing high throughput with high currents, such as a high powered e-beam.

Having united the mask wafer 105 and the device pattern wafer 202, the mask wafer 105 and the portion of the device pattern wafer 202 are exposed to the e-beam 216. In one or more cases, the e-beam 216 transfers the template device patterns 116 onto the third layer 204. In one or more cases, the e-beam 216 transfers the template device patterns 116 over the device pattern 218 of the device pattern wafer 202. That is, the electrons from the e-beam 216 pass through the template device patterns 114 and are exposed to the third layer 204, thereby transferring the template device patterns 114 from the template mask 116 onto the third layer 204 of the device pattern wafer 202. The mask wafer 105 may be exposed to an e-beam at or about 2 kV to 10 kV, and more preferably 3 kV.

In one or more cases, to separate the mask wafer 105 and the device pattern wafer 202, the mask wafer 105 may be moved to an edge of the device pattern wafer 202, such that the template device patterns 116 do not overlap the device pattern 218. That is, the mask wafer 105 is positioned on a pallet of a stage holding the semiconductor. By positioning the mask wafer 105 over the stage, the mask wafer 105 may be easily removed from the device pattern wafer 202. In one or more other cases, to separate the mask wafer 105 and the device pattern wafer 202, helium (He) may be introduced into grooves of the mask wafer 105 to create a floating force. The grooves may be located under the grid 120, and be positioned between the third layer 204 and at least one of the second layer 111 and the first layer 110. The floating force may cause a force to move the mask wafer 105 upwards, thereby separating the mask wafer 105 from the device pattern wafer 202.

In one or more cases, having transferred the template device patterns 114 onto the device pattern wafer 202, the mask wafer 105 may be aligned and united with another portion of the device pattern wafer 202. The mask wafer 105 may be aligned and united with the other portion of the device pattern wafer 202 in a same or similar manner as described herein. Having united the mask wafer 105 with the other portion of the device pattern wafer 202, the mask wafer 105 and the other portion of the device pattern wafer 202 are exposed to the e-beam 216, in which the e-beam 216 transfers the template device patterns 116 onto the other portions of the device pattern wafer 202 and/or over a device pattern of the other portion of the device pattern wafer 202. In one or more cases, the align, unite, and e-beam exposure process may be repeated on one or more additional portions of the device pattern wafer 202. For example, the align, unite, and e-beam exposure process may be repeated over each device pattern area of the device pattern wafer 202. In one or more cases, the LEECOPL system includes processes 100 and 200. By including the first layer 110 on the mask wafer 105, the LEECOPL is a single mask e-beam lithography system that does not need to utilize complementary masks as used in LEEPL.

FIG. 5A illustrates an example of E-optics and beam blur for a LEEPL system. FIG. 5B illustrates a graphical representation of a beam blur profile 87 for the LEEPL system of FIG. 5A. FIG. 5C illustrates an example of E-optics and beam blur for a LEECOPL system. FIG. 5D illustrates a graphical representation of a beam blur profile 89 for the LEECOPL system of FIG. 5C. FIG. 5E is an enlarged view of an example path E-optics and beam blur for the LEECOPL system of FIG. 5C. FIG. 5F is an enlarged view of an example path E-optics and beam blur for the LEECOPL system of FIG. 5C.

In the LEEPL system, during the e-beam exposure process, a mask 84 is separated from a wafer 80 by a gap distance 82. The gap distance 82 may be, for example, 40 micro meters. During the e-beam exposure process, an e-beam, such as the e-beam 215, is emitted from an emitter 88. The e-beam 215 passes from the emitter 88 though a wehnelt 81, an anode 83, a lens 85 and towards the mask 84. The mask 84 allows a portion of the e-beam 215 to pass through the mask 84 and prevents another portion of the e-beam 215 from passing through the mask 84. As the e-beam 215 moves through the gap distance 82, the e-beam 215 diverges by an angle α before contacting the wafer 80. The e-beam 215 may have a beam blur 86 of about 4 nanometers, as shown by the beam profile 87 in FIG. 5B.

In the LEECOPL system, contrary to the LEEPL system and conventional e-beam lithography, during the e-beam exposure process, the device pattern wafer 202 and the mask wafer 105 are united such that there is no gap or substantially no gap between the top of the third layer 204 and the bottom of the first layer 110. During the e-beam exposure process, the e-beam 216 is emitted from an emitter 88. The e-beam 216 passes from the emitter 88 though the wehnelt 81, the anode 83, the lens 85 and towards the mask wafer 105. As a portion 216a of the e-beam 216 passes the membrane 108, the portion 216a of the e-beam 216 may diverge by an angle α_{E0}. The portion 216a of the e-beam 216 may further diverge by an angle α_{CL} when passing through the first layer 110. The e-beam 216 may have a beam profile 89, as shown in FIG. 5D.

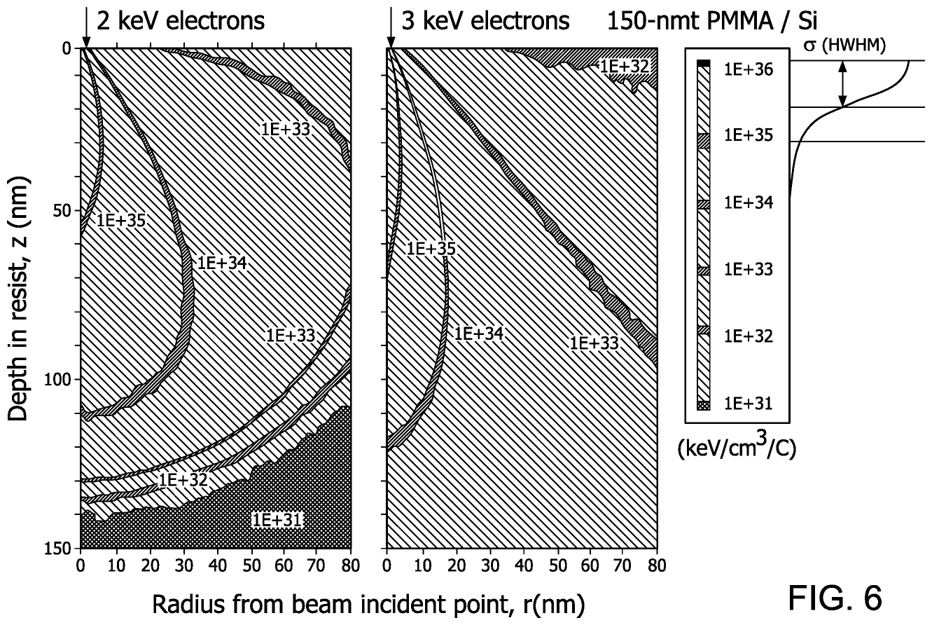

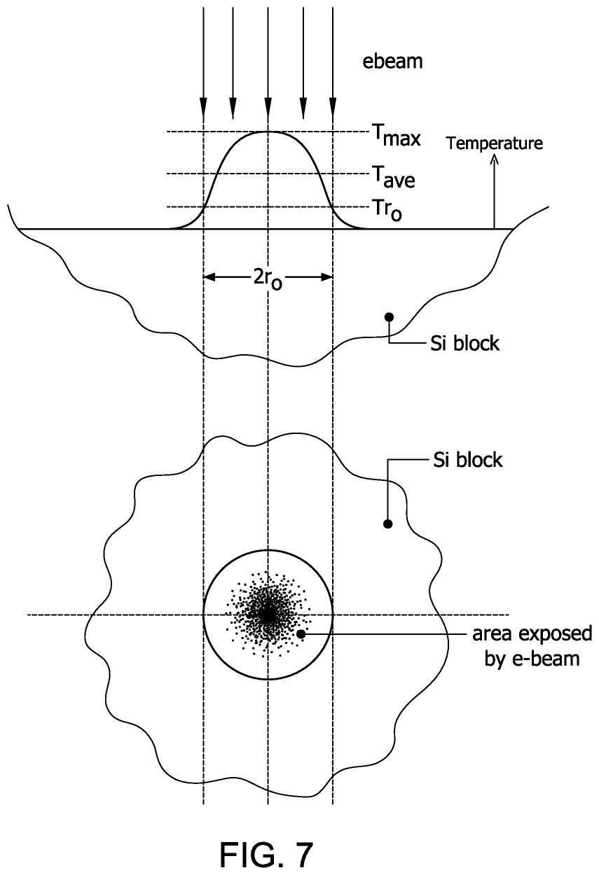

FIG. 6 is a simulation of a primary electron's forward-scattering profile. FIG. 7 illustrates a temperature rise causing thermal distortion of the mask wafer 105 and the device pattern wafer 202.

Resolution (R_{L/S}) of LEECOPL:

The resolution of the LEECOPL system may be estimated using the e-beam systems resolution formula. (Yamashita Jpn, J.Appl. Phys 44 (2004) 5590). According to the formula, the resolution: (R_{L/S} line and space resolution) can be obtained from (a) the forward scattering range of the primary electrons in the resist: β^{f}₍ₙₘ₎, and (b) the beam blur: ρ^{(nm)} of the e-beam system as

R_{L/S}=3√(β_{f}²+ρ²) (1)

in which R_{L/S} (nm) is the resolution, β_{f} is the forward scattering range, and ρ is the beam blur that is caused by the divergence of the e-beam, i.e., the deviation from the parallelism of the e-beam.

In order to estimate the beam blur 93 for LEECOPL, the beam blur for the LEEPL system may be estimated. For example, the e-beam optics of the LEEPL system may have a large gap distance 82 of 40 μm between the mask 84 and the resist layer on the wafer 80 and a measured beam blur 86 of 4 nm. Regarding the LEECOPL system that has no gap distance, the thickness of the membrane 108, as shown in FIG. 5C, may serve as the corresponding gap in the LEECOPL system. Therefore, assuming LEECOPL's e-optics is the same as that of LEEPL, the beam blur of LEECOPL system, i.e., (ρ_{E.O})_{LEECOPL}, can be obtained as follows:

$$\begin{matrix}{( {ρ}_{E . O} )}_{LEECOPL} = ρ LEEPL \cdot ( membrane thickness of LEECOPL ) / \\ ( gap distance between mask and resist of LEEPL ) \\ = 4 nm \times ( 100 nm / 40 \times {10}^{3} ( nm ) \\ = 1 \times {10}^{- 2} ( nm )\end{matrix} \qquad ( 2 )$$

in which ρLEEPL is the beam blur of the LEEPL system, e.g., 4 nm; the gap distance between mask 84 and the resist layer on the wafer 80 of LEEPL is 40 μm; and the thickness of the membrane 108 of the LEECOPL system is 100 nm.

A computer simulation, as shown in FIG. 6, may obtain the beam blur 93 due to the e-beam scattering by first layer 110, (ρ_{C.L}). The value of (ρ_{C.L}) is estimated to be 0.18 nm at 2 kV. The total e-beam blur of LEECOPL system may be (ρ_{E.O})+(ρ_{C.O})=0.01+0.18 nm=0.192 nm≈0.2 nm. Likewise, the forward scattering of the primary electron in resist, β_{f}, can be obtained by computer-simulation, as shown in FIG. 7. The values of β_{f} at the beam energy of 2 kV, 3 kV, 5 kV and 8 kV may be estimated as 4.5 nm, 3.0 nm, 1.8 nm, and 1.2 nm, respectively. The total e-beam blur, 0.2 nm, is smaller than β_{f} of equation (1). Therefore, the resolution, R_{L/S}, of LEECOPL system may be determined by the forward-scattering range β_{f} as

R_{L/S}=3√(βf²+ρ²ₜₒₜₐₗ)≈3√βf² (3)

Summarizing the above result, the resolution of LEECOPL system at various voltages is shown in Table 1.

TABLE 1
Resolution R_{L/S} (nm) of LEECOPL at various e-beam energy

| Beam Energy (kV) | Resist Thickness (nm) | βf (nm) | R_{L/S} (nm) |
|---|---|---|---|
| 2 | 20 | 4.5 | 13.5 |
| 3 | 25 | 3.0 | 9.0 |
| 5 | 30 | 1.8 | 5.4 |
| 8 | 35 | 1.2 | 3.6 |

in which the resist thickness is assumed as the beam penetrating depth where the forward-scattering goes to zero.

Thermal Distortion of the LEECOPL system:

As the membrane 108, the first layer 110, the second layer 111, the third layer 204, and the fourth layer 207 of the LEECOPL system are in a physical contact state, the membrane 108, the first layer 110, the second layer 111, the third layer 204, and the fourth layer 207 of the LEECOPL system may be considered thermally combined as one solid body. The thickness of the membrane 108, the first layer 110, the second layer 111, the third layer 204, and the fourth layer 207 may be smaller (e.g., at or about 200 nm) in comparison to the diameter of the exposed area (e.g., at or about 300 mm) of the device pattern wafer 202. Thus, it may be assumed that the temperature rise of these combined layers may be nearly the same as the temperature rise of the surface of the Si block model, as shown in FIG. 8, which is exposed to the e-beam. Moreover, the penetrating distance of a 3 kV e-beam may be within 200 nm, thus the total energy of the e-beam is deposited within these combined layers. Using the simulated model in FIG. 8, the temperature rise of the LEECOPL mask wafer 105 is calculated in in a closed form by the following equation.

Tₘₐₓ=pπr₀/4K√π=√πTₐᵥₑ

in which T₍ᵣ₎ is the temperature rise at the position r (cm), p is the input power density (W/cm²), r₀ is the radius of the bombarded area (cm), and K is thermal conductivity of Si block (W/cm° C.).

Assuming K of Silicon is 1.5 (W/cm° C.), Tₘₐₓ(° C.) may be obtained for currents: I(mA)=1 mA, 2 mA, and 3 mA, in which the energy (E) of the e-beam: E=2 kV, 3 kV, 5 kV, and 8 kV, the power (P) of the e-beam is shown in Table 2 below, and the radius of the membrane size r₀=1.5 cm.

TABLE 2
(Tₘₐₓ): Maximum temperature rise of LEECOPL
at various e-beam input energy

| I(mA) | E(kv) | P(w) | Tmax (° C.) |
|---|---|---|---|
| 1 | 2 | 2 | 0.073 |
| | 3 | 3 | 0.11 |
| | 5 | 5 | 0.18 |
| | 8 | 8 | 0.29 |
| 2 | 2 | 4 | 0.15 |
| | 3 | 6 | 0.22 |
| | 5 | 10 | 0.36 |
| | 8 | 16 | 0.58 |
| 3 | 2 | 6 | 0.22 |
| | 3 | 9 | 0.33 |
| | 5 | 15 | 0.54 |
| | 8 | 24 | 0.90 |

(Tₘₐₓ)₀, as shown above in Table 2, is the steady-state temperature rise while the time of exposure is infinite. Therefore, the actual temperature rise, T_{actual}, may be lower than (Tₘₐₓ)₀.

T_{actual}<(Tₘₐₓ)₀ (6)

In order to estimate the maximum thermal distortion, (Dₘₐₓ)₀, of the LEECOPL system, caused by (Tₘₐₓ)₀, the experimental data of (Tₘₐₓ)₁=8° K, (Dₘₐₓ)₁=30 nm, and r₁=2.0 cm, obtained in the case of LEEPL without thermal distortion correction, is applied to the following proportional relationship as follows:

(Dₘₐₓ)₀/(Dₘₐₓ)₁=r₀/r₁·(Tₘₐₓ)₀/(Tₘₐₓ)₁ (7)

Thus

(Dₘₐₓ)=(Dₘₐₓ)₁·r₀/r₁·(Tₘₐₓ)₀/(Tₘₐₓ)₁=2.8×(Tₘₐₓ)₀, where (Dₘₐₓ)₁=30 nm, r₀=1.5 cm, and r₁=2.0 cm (8)

Hence, the estimated maximum thermal distortion, (Dₘₐₓ)₀, of the LEECOPL system at various power inputs can be obtained, as shown in Table 3. As shown in Table 3, the LEECOPL system can be used to write patterns with the resolution of a few nanometers, which has a substantially small distortion, (Dₘₐₓ), of 0.4 nm at the largest current of 3 mA and energy of 5 kV. Both the resolution and thermal distortion of LEECOPL at various input power are summarized in Table 3. The final accuracy of the LEECOPL system may be provided by adding the line and space resolution (R_{L/S}) with the maximum thermal distortion (Dₘₐₓ). Dₘₐₓ may be the outward expansion due to the temperature rise generated by the input power. Therefore, the CD of the LEECOPL system may be considered as adding the line and space resolution (R_{L/S}) with the maximum thermal distortion (Dₘₐₓ).

TABLE 3
Resolution and Thermal Distortion
of LEECOPL at various input power.

| Energy | Current | Power | Tₘₐₓ | Dₘₐₓ | R_{L/S} | CD |
|---|---|---|---|---|---|---|
| (kV) | (mA) | (W) | (° C.) | (nm) | (nm) | (nm) |
| 1.0 | 2.0 | 2.0 | 0.073 | 0.2 | 13.5 | 13.7 |
| 2.0 | 1.0 | 2.0 | 0.073 | 0.2 | 13.5 | 13.7 |
| 1.0 | 1.0 | 1.0 | 0.036 | 0.1 | 13.5 | 13.6 |
| 2.0 | 0.5 | 1.0 | 0.036 | 0.1 | 13.5 | 13.6 |
| 2.0 | 1.5 | 3.0 | 0.11 | 0.3 | 13.5 | 13.8 |
| 1.0 | 1.0 | 3.0 | 0.11 | 0.3 | 9.0 | 9.3 |
| 2.0 | 2.5 | 5.0 | 0.18 | 0.5 | 13.5 | 14 |
| 3.0 | 1.7 | 5.0 | 0.18 | 0.5 | 9.0 | 9.5 |
| 5.0 | 1.0 | 5.0 | 0.18 | 0.5 | 5.4 | 5.9 |
| 3.0 | 2.7 | 8.0 | 0.29 | 0.8 | 9.0 | 9.8 |
| 5.0 | 1.6 | 8.0 | 0.29 | 0.8 | 5.4 | 6.2 |
| 8.0 | 1.0 | 8.0 | 0.29 | 0.8 | 3.6 | 4.4 |

Throughput of the LEECOPL system:

In a particulate e-beam system, such as LEEPL and LEECOPL, the statistical variation called Shot Noise may be compensated in order to obtain high quality imaging on the third layer 204. For example, the Shot Noise may be required to meet the ITRS's Criterion for the LER (Line Edge Roughness) Requirement. For exposure, if a number of electrons per CD² is 600, then the above criterion for the LER requirement is met. (“Shot Noise Effect and Throughput in LEEPL System” T.Utsumi Proc. of SPIE, Vol 6517, 65172 J (2007), Emerging Lithographics Technologies XI. Edited by M. J. Lercel, Advanced Semi-conductor Lithography Workshop, 2007, Puerto Rico). Therefore, the number of electrons per CD² at 1 mA×1 sec, assuming CD=10 nm, can be obtained as follows.

The current density of 1 mA per LEECOPL mask having a diameter d₀ of 3.0 cm is i₀=0.062 (mA/cm²); the electron flow per second cm² for 1 mA is n₀=3.9×10¹⁴ (number of electrons/mA·sec.·cm²); and the electron flow per second CD² for 1 mA, where CD=10 nm is n₀=3.9×10² (number of electrons/mA·sec.·CD²). The time needed to fill up 600 electron per CD² area is t_{cd}=1.53 sec. The time to cover the diameter d₀ of 300 mm for the device pattern wafer 202 in a step and repeat motion may be t₁₀₂=15 cm×15 cm×3.14/4 cm×4 cm=67.3 sec.

The throughput of 300 mm device pattern wafer 202 per hr at I=1 mA, CD=10 nm is

N_{wafer}^{1 mA}=3600 sec/67.3 sec=53.5 (300 mmφ W/hr) [11]

The throughput of the LEECOPL system for CD=16 nm, 10 nm, and 5 nm at various currents is provided in Table 4.

TABLE 4
Throughput of LEECOPL for CD = 16
nm, 10 nm, and 5 nm at various currents.

| | CD = 16 nm | CD = 10 nm | CD = 6 nm |
|---|---|---|---|
| 1 mA | 136 W/hr | 53 W/hr | 20 W/hr |
| 2 mA | 272 W/hr | 107 W/hr | 40 W/hr |
| 3 mA | 408 W/hr | 160 W/hr | 60 W/hr |
| 5 mA | 686 W/hr | 267 W/hr | 100 W/hr |

E-optics of the LEECOPL system:

The beam blur of the LEECOPL system is essentially negligible in comparison to the conventional LEEPL e-beam projection system. Therefore, the LEECOPL system does not require a sophisticated field emission e-beam optics. However, the LEECOPL system may require a rather large current in its optics, as the area for beam exposure may be as large as 15 cm×15 cm×3.14=706 cm², which corresponds to the size of 300 mmφ of the device pattern wafer 202. The appropriate current range for the system is considered to be 1 mA˜3 mA. As to the form of the e-beam optics, either scanning exposure type or overall exposure type may be used.

In one or more cases, direct contact between the membrane 108 and the third layer 204 and friction caused by the motion between the surfaces of the membrane 108 and the third layer 204 may cause damage to the patterned membrane 108. By forming a continuous and smooth first layer 110 of amorphous carbon on the membrane 108, additional layers may be added to the first layer 110 to protect the patterned membrane 108 and minimize friction between the patterned membrane 108 and the third layer 204. For example, the second layer 111, being a nonstick coating, such as polytetrafluoroethylene or Teflon™, may be applied to the first layer 110 and/or the third layer 204 to minimize the friction between the first layer 110 and the third layer 204. In another example, a super-accuracy air-bearing stage may be used for the align, unite, e-beam exposure, and repeat process. The super-accuracy air-bearing stage may maintain a gap of a few nanometers between the first layer 110 and the third layer 204. The super-accuracy air-bearing stage may maintain the gap of to 1 nm or about 1 nm during contact printing of the align, unite, e-beam exposure, and repeat process. Having separated the first layer 110 and the third layer 204 via the super-accuracy air-bearing stage, a chemically stable, low-vapor pressure lubricant may be introduced in the gap between the first layer 110 and the third layer 204. The lubricant may include, for example but not limited to, silicon based materials.

Resolution, R_{L/S}, of the LEECOPL system may be determined using a single parameter, which is the forward-scattering range of primary electrons in the third layer 204. This is possible because beam blur in the LEECOPL contact printing is negligibly small in comparison to the forward scattering range. The final accuracy, which is the CD, of the pattern obtained after the exposure and development of the third layer 204 may be provided by adding the line and space resolution (R_{L/S}) due to the forward-scattering in the third layer 204 with the maximum thermal distortion (Dₘₐₓ) due to the outward expansion of a temperature rise generated by input power. The thermal distortion (Dₘₐₓ), which may indicate the performance of the LEECOPL system, is determined by the input power of the exposure (W). The critical distance (CD) of the LEECOPL system may be, for example,

| E(kv) | P(w) | Tₘₐₓ (° C.) | Dₘₐₓ(nm) | R(L/S)(nm) | CD(nm) |
|---|---|---|---|---|---|
| 2 | 2 | 0.073 | 0.36 | 13.5 | 14 |
| 3 | 3 | 0.11 | 0.54 | 9.0 | 9.54 |
| 5 | 5 | 0.18 | 0.9 | 5.4 | 6.3 |
| 8 | 8 | 0.29 | 1.44 | 3.6 | 5.0 |

The throughput N_{w} (300 mmφ Wafer/Hr) may be

$$\begin{matrix}{N}_{w} = 320 ( W / {H}_{r} ) for CD = 16 nm \\ {N}_{w} = 150 ( W / {H}_{r} ) for CD = 10 nm \\ {N}_{w} = 50 ( W / {H}_{r} ) for CD = 6 nm\end{matrix} \} at I = 3 mA$$

Moreover, the LEECOPL system may utilize a long depth of focus (DOF) that is more suitable for the process of 3D integration than the shallow DOF of conventional optical systems. 3D integration may describe techniques that extend beyond fine Field Effect Transistors (FET) and tall wiring stacks. 3D integration may be used for a large integration of transistors by volume rather than area.

As used herein, the term “about” in reference to a numerical value means plus or minus 10% of the numerical value of the number with which it is being used.

The description of the embodiments of the present disclosure has been presented for purposes of illustration and description, but is not intended to be exhaustive or limited to the embodiments in the form disclosed. Many modifications and variations will be apparent to those of ordinary skill in the art without departing from the scope and spirit of the disclosure. The embodiments and examples were chosen and described in order to best explain the principles of the disclosure and the practical application, and to enable others of ordinary skill in the art to understand the disclosure for various embodiments with various modifications as are suited to the particular use contemplated.

It will be clear that the various features of the foregoing systems and/or methodologies may be combined in any way, creating a plurality of combinations from the descriptions presented above.

What is claimed is:

1. A method comprising:
forming a membrane in a substrate layer;
forming a first layer on a first back surface the substrate layer, the first layer being semitransparent;
forming a second layer on a second back surface of the first layer, the second layer formed from a material having a low coefficient of friction; and
writing one or more mask alignment marks and one or more template device patterns in the membrane, thereby forming a template mask wafer.

2. The method of claim 1, wherein the membrane is formed into a top portion of the substrate layer via etching.

3. The method of claim 1, wherein the membrane comprises a width ranging from 1 centimeter to 3 centimeters and a length ranging from 1 centimeter to 3 centimeters, and a thickness ranging from 30 nanometers to 200 nanometers.

4. The method of claim 3, wherein the membrane comprises a critical dimension of 10 nanometers or less.

5. The method of claim 1, wherein the first layer comprises a diamond film, amorphous carbon, or silicon.

6. The method of claim 1, wherein the first layer comprises a thickness ranging from 2 nanometers to 10 nanometers.

7. The method of claim 1, wherein the first layer acts as an etching stop when writing one or more template device patterns into the membrane.

8. The method of claim 1, wherein the one or more mask alignment marks and the one or more template device patterns are written in the membrane using Nanoimprint Lithography or an e-beam writer.

9. The method of claim 1, wherein the one or more mask alignment marks are arranged in the outer portion of the membrane.

10. The method of claim 1, further comprising forming a resist layer on a top surface of the membrane,
wherein writing the one or more mask alignment marks and the one or more template device patterns further comprises writing the one or more mask alignment marks and the one or more template device patterns into the membrane and the resist layer.

11. The method of claim 1, further comprising:
positioning the template mask wafer on a device pattern wafer;
aligning the one or more mask alignment marks of the template mask wafer with one or more alignment marks of the device pattern wafer; and
transferring the one or more template device patterns of the template mask wafer onto the device pattern wafer.

12. The method of claim 11, wherein the device pattern wafer comprises a semiconductor wafer, a third layer formed on the semiconductor wafer, and a fourth layer formed on the third layer, and
wherein the one or more template device patterns are transferred onto the third layer.

13. The method of claim 12, wherein positioning the template mask wafer on the device pattern wafer comprises positioning the second layer of the template mask wafer on the third layer and the fourth layer such that the second layer directly contacts the fourth layer.

14. The method of claim 13, wherein the one or more template device patterns are transferred onto the third layer via an electron-beam projection process, and wherein there is no beam-blur as an electron-beam passes through the template mask.

15. The method of claim 11, wherein transferring the one or more template device patterns comprises exposing the template mask wafer and the device pattern wafer to an electron beam, and
wherein the electron beam ranges from 2 kilovolts to 8 kilovolts.

16. A single template mask electron-beam projection method, the method comprising:
positioning the template mask wafer on a device pattern wafer,
the template mask wafer comprising a membrane formed in a substrate layer, a first layer disposed on a first back surface of the substrate layer, one or more mask alignment marks and one or more template device patterns in the membrane, and a second layer disposed on a second back surface of the first layer, and
the device pattern wafer comprising a semiconductor wafer, a third layer on a semiconductor wafer, one or more alignment marks in the third layer, and a fourth layer on the third layer;
aligning the one or more mask alignment marks of the template mask wafer with the one or more alignment marks of the device pattern wafer; and
transferring the one or more template device patterns onto the device pattern wafer,
wherein the first layer is semitransparent, and the second layer has a low coefficient of friction.

17. The method of claim 16, wherein positioning the template mask wafer on the device pattern wafer comprises positioning the second layer of the template mask wafer on the third layer and the fourth layer such that the second layer directly contacts the fourth layer.

18. The method of claim 17, wherein the one or more template device patterns are transferred onto the third layer via an electron-beam projection process, and wherein there is no beam-blur as an electron-beam passes through the template mask.

19. The method of claim 16, wherein transferring the one or more template device patterns comprises exposing the template mask wafer and the device pattern wafer to an electron beam.

20. The method of claim 18, wherein the electron beam ranges from 2 kilovolts to 8 kilovolts.
